(19) United States
(12) Patent Application Publication
(10) Pub. No.: US 2004/0085140 A1
(43) Pub. Date: May 6, 2004

(54) Clock signal generating circuit

(75) Inventor: Seung Hyun Yi, Gyeonggi-do (KR)

Correspondence Address: Jonathan Y. Kang, Esq., Lee & Hong P.C., 14th Floor, 801 South Figueroa Street, Los Angeles, CA, 90017, US

(73) Assignee: LG Electronics Inc.

(21) Appl. No.: 10/688,684

(22) Filed: Oct. 17, 2003

(30) Foreign Application Priority Data
Oct. 18, 2002 (KR) P2002-63679

(51) Int. Cl. H03L 7/00

(52) U.S. Cl. 331/16

(57) ABSTRACT

A method for detecting a phase difference between an input clock signal and a feedback output clock signal, correcting by delaying time corresponding to the phase difference, and generating a phase control signal delayed for a time period corresponding to the phase difference is disclosed.

A 50% duty factor is sustained by delaying the phase control signals delayed for a period time corresponding to the phase difference for a predetermined period of time. In this case, the preset time is set to compensate a delayed time of the circuit element whereby the phase control signal passes.

### CROSS-REFERENCE TO RELATED APPLICATIONS

This application claims the benefit of Korean Application No. P2002-63679 filed on Oct. 18, 2002, which is hereby incorporated by reference as if fully set forth herein.

### BACKGROUND OF THE INVENTION

1. Field of the Invention

The present invention relates to a circuit for generating a clock signal, and more particularly, to a clock signal generating circuit for sustaining 50% duty factor.

b 2. Discussion of the Related Art

In general, when clock signals having a plurality of frequencies are generated using clock signals having predetermined frequencies, a PLL circuit (Phase Lock Loop) is employed. Basic principle of getting clock signals having a plurality of frequencies through such PLL circuit is relatively simple.

First, the PLL circuit moves input clock signals to 90°, 180°, 270°, 360° using a charge pump circuit. In this case, a falling edge of an output clock signal is generated using the clock signals shifted to 90° and 270°, a rising edge of the output signal is generated using the clock signals shifted to 180° and 270°. Therefore, the PLL circuit generates the output clock signal having a frequency two times the frequency of the input clock signal.

Meanwhile, a duty factor is a value a high state time period of the clock signal is divided by a cyclic period of the clock signal. If the duty factor is sustained at 50% exactly, the high state time period of the clock signal is the same as a low state time period of the clock signal.

There is a difficulty in sustaining a 50% duty factor exactly in a conventional VSLI (Very Scale Integration) and an application circuit receiving a clock signal having a predetermined frequency and performing a predetermined action, and errors in performing of the VLSI and the application circuit are often generated.

In other words, if the duty factor fails to be at 50% exactly, the application circuit operative at a rising edge and a falling edge of the clock signal malfunctions, and a predetermined signal performing with the clock signal is not generated at an exact place. Therefore, it is important that the duty factor is sustained at 50%, exactly.

However, conventional circuits for generating clock signal are analogous with a complicate system and difficulty of fabrication and values of parts such as a resistance and a condenser of the analog circuits should be accurately set. Moreover, there is a difficulty in sustaining the duty factor at 50% exactly.

Since there is a difficulty in sustaining the duty factor at 50% , each of the PLL circuits has to be differently designed to get the output clock signal having a plurality of frequencies.

### SUMMARY OF THE INVENTION

Accordingly, the present invention is directed to a clock signal generating circuit that substantially obviates one or more problems due to limitations and disadvantages of the related art.

An object of the present invention is to provide a clock signal generating circuit receiving an input clock signal having a plurality of frequencies using simple digital devices, and generating an output clock signal having frequencies corresponding to plural times the frequency of the input clock signal.

Another object of the present invention is to provide a clock signal generating circuit for synchronizing the input click signal and the output clock signal to sustain a duty factor at 50% exactly.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, the clock generating circuit including a phase comparator for detecting a difference between the input clock signal and the feedback output signal and generating a shift control signal, a phase control signal generator for receiving the input clock signal and generating the phase control signal using a predetermined clock generating reference signal according to the shift control signal, a clock signal generator for receiving the phase control signal and generating the output clock signal having frequencies corresponding to a plurality of times the frequency of the input clock signal.

The phase comparator outputs a shift control signal commanding a left shift if the phase of the output clock signal is faster than that of the input clock signal and a shift control signal commanding a right shift if the phase of the output clock signal is slower than that of the input clock signal.

In another aspect of the present invention, a phase control signal generator includes a shift register for storing a predetermined clock generating reference signal beforehand and shifting the clock generating reference signal according to the shift control signal, a synchronized signal providing part connected to the shift register for synchronizing the shifted clock generating reference signal, a plurality of delay loops connected to the synchronized signal providing part and generating a plurality of the phase control signal by delaying the preset time as long as the time set according to the shifted position of the clock generating reference signal.

In this case, the shift register stores a high voltage clock generating reference signal to an output terminal and all of low voltage clock generating reference signals to the rest of the terminals. Each of the plurality of delay loops includes a plurality of delays for delaying n (natural number) times the preset time.

The clock signal generator includes a plurality of correction delays delaying the phase control signal for a time period differently set numbers of times a preset time period on the basis of a preset time, a plurality of pulse signal generators for generating a predetermined pulse signal according to the delayed phase control signal, and a clock signal generator generating the output clock signal according to the pulse signal.

In this case, each of the plurality of the pulse signal generators includes a plurality of a first inverters for inverting and delaying the phase control signal for a preset time, an NAND gate for inverting and logically multiplying the delayed phase control signal and the output signals from the plurality of inverters, and a second inverter for inverting the output signal of the NAND gate.

The clock signal outputter includes a PMOS transistor and an NMOS transistor connected in series between an outlet and a grounding, a plurality of third inverters connected to a connection point of the PMOS transistor and the NMOS transistor for *working by latch, a fourth inverter connected to the latch for inverting an input signal.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIG. 1 is a block diagram illustrating a clock signal generating circuit according to the present invention.

FIG. 2 is a block diagram illustrating a phase control signal generator 200.

FIG. 3 is a block diagram illustrating a clock signal generator 300.

FIG. 4 is a block diagram illustrating a pulse signal generator.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

The present invention detects a phase difference of an input clock signal and a feedback output clock signal, delays for a time period according to the phase corresponding to the phase difference to correct, and generates a phase control signal delayed for a time period according to the phase difference on the basis of the clock generating reference signal and a clock signal having n times frequency by delaying the delayed phase for a preset time. In this case, the preset time is set to compensate the delayed time of the circuit element.

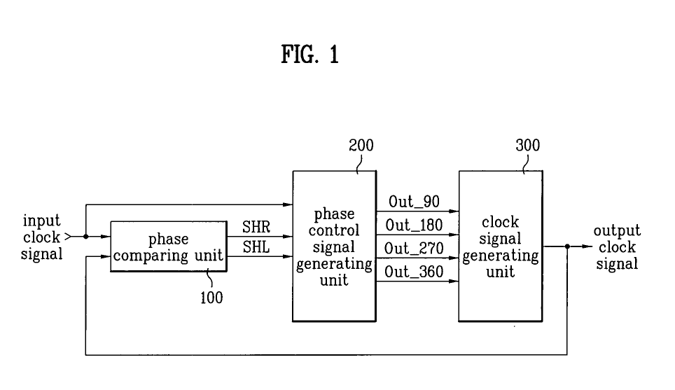

Hereinafter, a preferred embodiment will be described according to the present invention. FIG. 1 is a block diagram illustrating a clock signal generating circuit in accordance with the present invention. As illustrated in FIG. 1, the clock signal generating circuit includes a phase comparator 100 for generating shift control signals (SHR, SHL) detecting the phase difference of an input clock signal and an output clock signal, a phase control signal generator 200 for generating a plurality of phase control signals (OUT_90, OUT_180, OUT_270, OUT_360) receiving the input clock signal and using a predetermined standard signal for generating clock in accordance with the shift signals (SHR, SHL), a clock signal generator 300 for receiving a plurality of phase control signals (OUT_90, OUT_180, OUT_270, OUT_360), and generating the output clock signal having a frequency corresponding to plural times a frequency of the input clock signal.

The phase comparator 100 receives the input clock signal having a predetermined frequency and an output clock signal generated by the present invention, detects the phase difference between the input signal and the output signal, and selectively outputs shift control signals (SHR, SHL) in accordance with the detected phase difference.

In other words, the phase comparator 100 generates the shift control signal (SHL) commanding a left shift when the phase of the output signal is faster than the input signal and the shift control signal (SHL) commanding a right shift when the phase of the output signal is slower than the input signal.

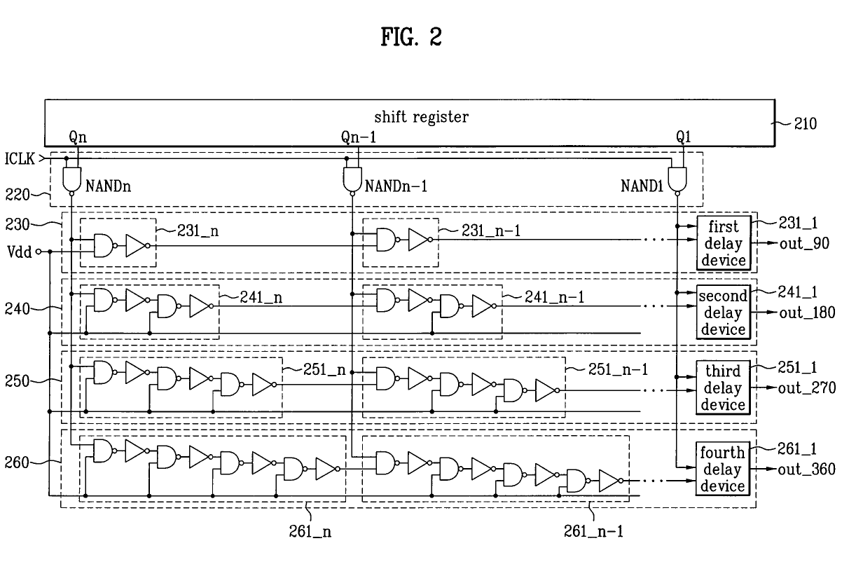

FIG. 2 is a block diagram illustrating a phase control signal generator 200 of FIG. 1. As illustrated in FIG. 2, the phase control signal generator 200 includes a shift register 210 for shifting a clock generating reference signal in left/right direction according to shift control signals (SHR, SHL) after storing a predetermined clock generating signal, a synchronized signal providing part 220 for synchronizing the clock generating reference signal from the shift register 210 to the input clock signal, a first to fourth delay loops (230, 240, 250, 260) for respectively generating phase control signals (OUT_90, OUT_180, OUT_270, OUT_360) delayed for each corresponding times according to a shifted location of the input clock signal.

The first to fourth delay loops (230, 240, 250, 260) connected to the synchronized signal providing part 220 includes a plurality of first delay 231 for delaying once of a preset time, a plurality of second delay 232 for delaying two double of a preset time, a plurality of third delay 233 for delaying treble of a preset time, a plurality of fourth delay 234 for delaying quadruple of a preset time.

The phase control signal generator 200 stores the clock generating reference signal of high phase to an output terminal of one of a plurality of output terminals of the shift register 210 and the clock generating reference signal of low phase to the rest of the output terminals of the shift register 210, and then shifts the clock generating signals in left/right direction in accordance with the shift control signals (SHR, SHL).

Therefore, *after inverting, into low phase, the clock generating signal of high phase to which one of NAND gates (NAND1, NAND2, . . . , NANDn) of the synchronized signal providing part 220 is stored, the phase control signal generator 200 receives the input signal and outputs the inverted clock generating reference signals to the first to the fourth loops (230, 240, 250, 260), respectively, in accordance with the input clock signal.

The first to the fourth loops (230, 240, 250, 260) apply the phase control signals (OUT_90, OUT_180, OUT_270, OUT_360), respectively, generated by delaying once to quadruple of a set time in accordance with the shifted location of the clock generating reference signal.

For example, when the clock generating reference signal is generated from Q1 among the output terminals of the shift register 210, NAND gate (NAND1) outputs the clock generating reference signal. A set of the first to fourth delay (231_1, 241_1, 251_1, 261_1), then, receives the inverted clock generating reference signal and delays and outputs each of the signals as the phase control signals (OUT_90, OUT_180, OUT_270, OUT_360).

When the clock generating reference signal is generated from Q2 among the output terminals of the shift register 210, NAND gate (NAND2) outputs the clock generating reference signal. Two sets of the first to fourth delay (231_2, 241_2, 251_2, 261_2), then, receives the inverted clock generating reference signal and delays and outputs each of the signals as the phase control signals (OUT_90, OUT_180, OUT_270, OUT_360).

In such way, when the clock generating reference signal is generated from Qn among the output terminals of the shift register 210, NAND gate (NANDn) outputs the clock generating reference signal. Then, n sets of the first to fourth delay (231_n, 241_n, 251_n, 261_n) receives the inverted clock generating reference signal and delays and outputs each of the signals as the phase control signals (OUT_90, OUT_1 80, OUT_270, OUT_360).

In other words, the fourth delay loop (260) generates the phase control signal (OUT_360) by delaying the clock generating reference signal outputted from the synchronized signal providing part 220 of the phase control signal generator 200 for a time period four times longer than a preset time set according to the shifted position of the clock generating reference signal. Also, first to third delay loops (230, 240, 250) generate the phase control signals (OUT_90, OUT_180, OUT_270) the phase control signals (OUT_90, OUT_180, OUT_270) by delaying the cock generating signal for a time period one to third times longer than the preset time set according to the shifted position of the clock generating reference signal.

Therefore, the phase control signal generator (200) generates the phase control signals (OUT_90, OUT_180, OUT_270, OUT_360) of which the phase difference between the input clock signal and the feedback output clock signal is corrected and applies to the clock signal generator (300).

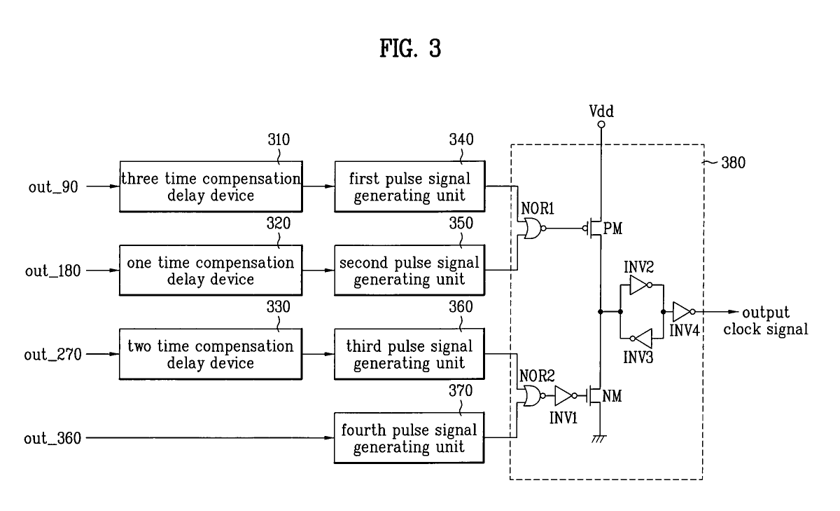

FIG. 3 is a block diagram illustrating a clock signal generator of FIG. 1. As illustrated in FIG. 3, the *clock signal generator (300) includes three, one and two times correction delays (310, 320, 330) for delaying the phase control signal delayed for the shortest time at the phase control signal generator 200 for a time period three, one and two times longer than the time needed until the output clock signal is generated; a first to fourth pulse signal generator (340, 350, 360, 370) for generating a predetermined pulse signal according to the three, one and two times correction delays (310, 320, 330) and the phase control signal (OUT_90); and a clock signal outputter 380 for generating clock signals having 360° and 180° phases according to the pulse signals generated by the first and second generators 340, 350 and having 27020 and 90° phases according to the third and fourth pulse signal generators 360, 370.

The clock signal outputter 380 generates the output clock signal by being connected to the inverter (INV4) through the PMOS and NMOS transistors (PM, NM) connected in series between an outlet and grounding.

In this case, terminals of the first and second pulse signal generators (340, 350) are connected to a gate of the PMOS transistor (PM); terminals of the third and fourth pulse signal generators (340, 350) are connected to a gate of the NMOS transistor (NM) through an NOR gate (NOR2) and an inverter (INV1).

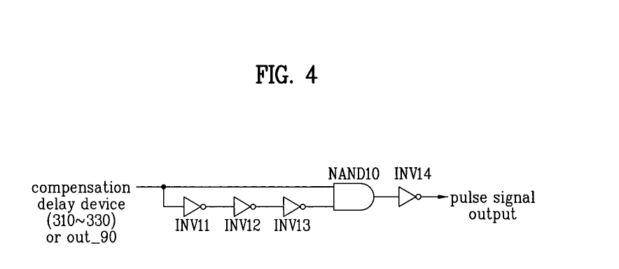

FIG. 4 is a block diagram illustrating a pulse signal generator of FIG. 3. As illustrated in FIG. 4, the pulse signal generators (340, 350, 360, 370) include an NAND gate (NAND10) and a plurality of inverters (INV11, INV2, INV3).

In other words, an input terminal of the pulse signal generators (340, 350, 360, 370) is connected directly to an input terminal on a first side of the NAND gate (NAND10) and, on the other hand, connected to an input signal at a second side of the NAND gate (NAND10) through the plurality of inverters (INV11, INV12, INV13). An output terminal of the NAND gate (NAND10) is connected to the input terminal of the inverter (INV14) and the pulse signal is generated from the output terminal of the inverter (INV14).

The clock signal generator 300 composed as aforementioned receives the phase control signals (OUT_90, OUT_180, OUT_270, OUT_360) of which the phase difference of the input clock signal and the feedback output clock signal is corrected and generating the output clock signal having a frequency corresponding to two times the frequency of the input clock signal.

In other words, each of the three-times, one-time and two-times delays (310, 320, 330) receives and delays the phase control signals (OUT_180, OUT_270, OUT_360) for a time period three times, one time and two times longer than the time required to generate the output clock signal according to one phase control signal (OUT_90) delayed the shortest time at the phase control signal generator 200, and applies to the first to fourth generators (340, 350, 360, 370). In other words, the time delayed at the pulse signal generators (340, 350, 360, 370) and the clock signal outputter 380.

The first to fourth pulse signal generators (340, 350, 360, 370) receives the phase control signal (OUT_90) and the delayed phase control signals (OUT_180, OUT_270, OUT_360) for three times, one time and two times longer than the set time, and applies the signals to the input terminal on a first side of the NAND gate (NAND10), and, the first to fourth pulse generators (340, 350, 360, 370) delay and invert the phase control signals (OUT_180, OUT_270, OUT_360) delayed for three times, one time and two times longer than the set time and the phase control signal (OUT_90) to a plurality of inverters for delaying (INV11, INV12, INV13) respectively, and applies to a second side of the NAND gate (NAND10). The NAND gate (NAND10) then generates a low voltage pulse signal with a predetermined width in accordance with the phase control signals (OUT_90, OUT_180, OUT_270, OUT_360), and the inverter (INV14) inverts the low voltage pulse signal and applies to each of the NOR gate (NOR 1,NOR 2) of the clock signal outputter (380).

The NOR gate (NORI) of the clock signal outputter (380) carries out invert-logical multiply according to the phase control signals (OUT_180, OUT_270, OUT_360) generated from the first and second pulse signal generators (340, 350), and applies to a gate of the PMOS transistor (PM) to be connected to the NMOS transistor (NM).

Therefore, the phases of connected point of the PMOS transistor (PM) and the NMOS (NM) are changed to high voltage phases according to the first and second pulse signal generators (340, 350) and to low voltage phases according to the third and fourth pulse signal generators (360, 370). The phases of connection point between the PMOS transistor (PMOS) and the NMOS transistor (NM) is inverted and stored to the latch including inverters (INV2, INV3), is inverted and outputted as the output signal.

In other words, the phase control signal (OUT_360) is delayed for a period of time three times longer than the time required for the phase control signal (OUT_360) be inputted to the three times correction delay (310) of the clock signal generator 300 and to be passed through the first pulse signal generator (340) and the clock signal outputter (380), and then delayed four times longer in total and accorded with the 360° output clock signal.

The phase control signal (OUT_180) is inputted to the one-time correction delay (320) of the clock signal generator (300), is delayed for a time period to be two times of a time period required to pass the second pulse signal generator (350) and the clock signal outputter (380), and passes the second clock pulse signal generator (350) and the clock signal outputter (380), and is accorded with 180° output clock signal after being delayed for a two times longer time period in total.

The phase control signal (OUT_270) is inputted to the two-times correction delay (330) of the clock signal generator (300), is delayed for a time period to be two times of a time period required to pass the third pulse signal generator (360) and the clock signal outputter (380), and passes the third clock pulse signal generator (360) and the clock signal outputter (380), and is accorded with 270° output clock signal after being delayed for a three times longer time period in total.

The phase control signal (OUT_90) is passes through the fourth pulse signal generator (370) and the clock signal outputter (380) after being delayed for a one-time longer period in total and is accorded with the 900 output clock signal.

Namely, 90°, 180° and 270° clock generating control signals of the output clock signal are generated by delaying for ¼, ½ and ¾ period on the basis of 360° clock generating control signal.

Meanwhile, the phase comparator (100) receives the output clock signal and compares with the phase of the input clock signal, generates the phase control signal (OUT_360) shifting the clock generating reference signal stored in the shift register 210 of the phase control signal generating part 200 on the result of the comparison, and outputs 360° clock generating control signal of the output clock signal at the clock signal outputter 380 according to the phase control signal (OUT_360).

Therefore, the output clock signal is accorded with the phase of the input clock signal and the frequency becomes two times, and the duty factor becomes 50% exactly.

Meanwhile, as described above, a method of generating the output clock signal having two times frequency of the input clock signal is described in the first embodiment of the present invention, but it will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

The phase control signal generating part 200 generates phase control signals such as six to eight numbers by delaying for a time period to be preset times of a preset time period and the clock signal generator 300 generates output clock signals having three to four times the frequency of the input signal according to the phase control signals such as six and eight numbers.

As aforementioned above, the clock signal generating circuit according to the present invention is able to sustain the duty factor at 50% by synchronizing the input clock signal and the output clock signal using the plurality of delay loops.

Furthermore, the clock signal generating circuit according to the present invention employs only digital circuits to generate output clock signals corresponding to the frequency of input clock signals and has an effect of applying to various application circuits with a simple system and ease of fabrication.

What is claimed is:

1. A circuit for generating a clock signal, comprising:
a phase comparator for detecting a difference between a predetermined input clock signal and feedback of an output clock signal, and generating a shift control signal;
a phase control signal generator for receiving the input clock signal and generating the phase control signal according to the shift control signal using a predetermined clock generating reference signal;
a clock signal generator for receiving the phase control signal and generating an output clock signal having a frequency corresponding to a plurality times the frequency of the input clock signal.

2. The circuit for generating the clock signal in claim 1, wherein the phase comparator outputs a shift control signal commanding a left shift when the phase of the output clock signal is faster than that of the input clock signal and outputs a shift control signal commanding a right shift when the phase of the output signal is slower than the that of the input clock signal.

3. The circuit for generating the clock signal in claim 1, wherein the phase comparator comprises:
a shift register for storing a predetermined reference signal beforehand and shifting the clock generating reference signal according to the shift control signal;
a synchronized signal providing part connected to the shift register for synchronizing the shifted clock generating reference signal;
a plurality of delay loop connected to the synchronized signal providing part for generating a plurality of phase control signal by delaying set time according to the shifted location of the clock generating reference signal.

4. The circuit for generating the clock signal in claim 3, wherein the shift register stores high phase clock generating reference signals to an output terminal and all of low phase clock generating signals to the rest of the output terminals.

5. The circuit for generating the clock signal in claim 3, wherein each of the plurality of delay loops comprises a plurality of delays for delaying the clock generating reference signals for ‘n’ (a natural number) times longer than a preset time period.

6. The circuit for generating the clock signal in claim 5, wherein the preset time is set according to the clock generating reference signals outputted from the synchronized signal providing part.

7. The circuit for generating the clock signal in claim 1, wherein the clock signal generator comprises:
a plurality of correction delay for delaying the phase control signal for a time period according to the predetermined set time;
a pulse signal generator for generating a predetermined pulse signal according to the delayed phase control signal;
a clock signal outputting part for outputting output the output clock signal according to the pulse signal.

8. The circuit for generating the clock signal in claim 7, wherein each of the plurality of correction delays receives and delays the phase control signals on the basis of required time from generating the pulse signals at the plurality of pulse signal generators to generating output clock signals.

9. The circuit for generating the clock signal in claim 7, wherein the plurality of pulse signal generator comprises:
a plurality of first inverters for inverting and delaying for a preset time the delayed phase control signal and a phase control signal not delayed;
a NAND gate for inverting and logical-multiplying the delayed phase control signal and the output signals from the plurality of inverters;
a second inverter for inverting output signals from the NAND gate.

10. The circuit for generating the clock signal in claim 7, wherein the clock signal generator comprises:
a PMOS transistor and an NMOS transistor connected in series between an outlet and a grounding;
a plurality of third inverters connected to a connection point of the PMOS transistor and the NMOS transistor for working by latch;
a fourth inverter connected to the latch for inverting input signals.

11. The circuit for generating the clock signal in claim 10, wherein PMOS transistor gate is connected to the output terminal of the plurality of pulse signal generators through a first NOR gate and the NMOS transistor gate through a second NOR gate and a fifth inverter.
